(19) United States
(12) Patent Application Publication
(10) Pub. No.: US 2023/0411418 A1
(43) Pub. Date: Dec. 21, 2023

(54) IMAGING SENSING DEVICE AND METHOD OF MANUFACTURING THE SAME

(71) Applicant: SK hynix Inc., Icheon-si (KR)

(72) Inventors: Hyun Soo LIM, Icheon-si (KR); Seung Hoon SA, Icheon-si (KR)

(21) Appl. No.: 18/075,354

(22) Filed: Dec. 5, 2022

(30) Foreign Application Priority Data
Jun. 14, 2022 (KR) 10-2022-0072312

(51) Int. Cl. H01L 27/146

(52) U.S. Cl. CPC H01L 27/14614; H01L 27/14689; H01L 27/14643

(57) ABSTRACT

An image sensing device may include a substrate, a first gate, a photoelectric converter, a first semiconductor pattern including a floating diffusion, a second semiconductor pattern and a second gate. The substrate includes a light-receiving region and at least one active region. The first gate is arranged over the light-receiving region. The photoelectric converter is formed in the light-receiving region such that a first end of the first gate is disposed over the photoelectric converter. The first semiconductor pattern is formed over the substrate at a second end of the first gate. The first semiconductor pattern has a first height. The second semiconductor pattern is formed over the active region of the substrate. The second semiconductor pattern has a second height. The second gate is formed over the active region of the substrate to cover the second semiconductor pattern.

### CROSS-REFERENCES TO RELATED APPLICATION

This patent document claims the priority and benefits of Korean application number 10-2022-0072312 filed on Jun. 14, 2022, which is incorporated herein by reference in its entirety.

### TECHNICAL FIELD

The technology and implementations disclosed in this patent document generally relate to an electronic device and a method of manufacturing the same, and more particularly to an imaging sensing device and a method of manufacturing the image sensing device.

### BACKGROUND

An imaging sensing device is used in electronic devices to convert optical images into electrical signals. With the recent development of automotive, medical, computer and communication industries, the demand for high-performance image sensors has been increasing in various electronic devices such as smart phones, digital cameras, camcorders, personal communication systems (PCS), game devices, security cameras, medical micro-cameras, robots, and UV sensing devices.

CMOS image sensing devices can convert optical images into electrical signals using simple circuits. In addition, CMOS image sensing devices are fabricated using the CMOS fabrication technology, and thus CMOS image sensors and other signal processing circuitry can be integrated into a single chip, enabling the production of miniaturized CMOS image sensing devices, low power consumption image sensors at a lower cost.

### SUMMARY

In some example embodiments, an image sensing device may include a substrate, a light-receiving region supported by the substrate to receive incident light and structured to include a photoelectric converter configured to detect the incident light to generate photo-charge carrying an image in the incident light, at least one active region supported by the substrate and located adjacent to the light-receiving region, a first gate formed over an upper surface of the substrate such that a first end of the first gate is disposed over the photoelectric converter, a first semiconductor pattern formed over the upper surface of the substrate at a second end of the first gate opposite to the first end and including a floating diffusion region, the first semiconductor pattern having a first height from the upper surface of the substrate, a second semiconductor pattern formed over the upper surface of the substrate corresponding to the active region, the second semiconductor pattern having a second height from the upper surface of the substrate, and a second gate formed over the upper surface of the substrate corresponding to the active region to cover the second semiconductor pattern.

In some example embodiments, an image sensing device may include a substrate, first and second semiconductor patterns supported by the substrate and protruding from the substrate, the first semiconductor pattern including a floating diffusion region, at least one photoelectric converter configured to detect incident light to generate photo-charge carrying an image in the incident light, the at least one photoelectric converter formed in a portion of the substrate adjacent to the floating diffusion region to generate photo-charge corresponding to incident light, at least one transfer transistor supported by the substrate and configured to transfer the photo-charge generated by the at least one photoelectric converter to the floating diffusion region in response to a transfer signal, a reset transistor supported by the substrate and configured to initialize the floating diffusion region to a power voltage level in response to a reset signal, a drive transistor supported by the substrate and configured to generate an output signal corresponding to an amount of the photo-charge stored in the floating diffusion, and a selection transistor supported by the substrate and configured to output the output signal generated by the drive transistor, in response to a selection signal, wherein at least one of the reset transistor, the drive transistor or the selection transistor comprises a fin gate structured to surround a side surface and an upper surface of the second semiconductor pattern.

In some example embodiments, a method of manufacturing an image sensing device may include forming a first insulation layer on a substrate that includes a light-receiving region and an active region adjacent to the light-receiving region, wherein the light-receiving region includes a photoelectric converter configured to detect incident light to generate photo-charge carrying an image in the incident light, selectively etching the first insulation layer to form a first opening to partially expose the light-receiving region of the substrate and a second opening to partially expose the active region of the substrate, forming first and second semiconductor patterns on the substrate exposed through the first and second openings, forming a second insulation layer on the first insulation layer, the first semiconductor pattern and the second semiconductor pattern, forming a gate conductive layer on the second insulation layer, etching the gate conductive layer, the second insulation layer and the first insulation layer to form a first gate over the light-receiving region of the substrate and a second gate over the active region of the substrate, and implanting impurities into the first semiconductor pattern to form a floating diffusion.

In some example embodiments, an image sensing device may include a substrate, a first gate, a photoelectric converter, a first semiconductor pattern, a floating diffusion, a second semiconductor pattern and a second gate. The substrate may have a light-receiving region and at least one active region adjacent to the light-receiving region. The first gate may be arranged on the substrate in the light-receiving region. The photoelectric converter may be formed in the light-receiving region at one side of the first gate. The first semiconductor pattern may be elevated from the substrate at the other end of the first gate. The first semiconductor pattern may have a first height. The floating diffusion may be formed in the first semiconductor pattern. The second semiconductor pattern may be elevated from the substrate in the active region. The second semiconductor pattern may have a second height. The second gate may be formed on the substrate in the active region to cover the second semiconductor pattern.

In some embodiments, an image sensing device may include a first semiconductor pattern, a second semiconductor pattern, a floating diffusion, at least one photoelectric converter, at least one transfer transistor, a reset transistor, a drive transistor and a selection transistor. The first and second semiconductor patterns may protrude from a substrate. The floating diffusion may be formed at the first semiconductor pattern. The photoelectric converter may be formed in the substrate adjacent to the floating diffusion to generate a photo-charges corresponding to an incident light. The transfer transistor may transfer the photo-charges generated from the photoelectric converter to the floating diffusion in response to a transfer signal. The reset transistor may initialize the floating diffusion to a power voltage level in response to a reset signal. The drive transistor may generate an output signal corresponding to an amount of the photo-charges stored in the floating diffusion. The selection transistor may output the output signal from the drive transistor in response to a selection signal. A gate of at least one of the reset transistor, the drive transistor and the selection transistor may have a fin gate structure configured to make contact with a side surface and an upper surface of the second semiconductor pattern along a channel width direction.

In some embodiments, a method of manufacturing an image sensing device forming a first insulation layer on a substrate. The substrate may have a light-receiving region and an active region adjacent to the light-receiving region. The first insulation layer may be selectively etched to form a first opening configured to partially expose the substrate in the light receiving region and a second opening configured to partially expose the substrate in the active region. A first semiconductor pattern and a second semiconductor pattern may be formed on the substrate exposed through the first opening and the second opening. A second insulation layer may be formed on a structure including the first semiconductor pattern and the second semiconductor pattern. A gate conductive layer may be formed on the second insulation layer. The gate conductive layer, the second insulation layer and the first insulation layer may be selectively etched to form a first gate in the light receiving region and a second gate in the active region. Impurities may be implanted into the first semiconductor pattern to form a floating diffusion.

### BRIEF DESCRIPTION OF THE DRAWINGS

FIG. 1 is a block diagram illustrating an image sensing system based on some embodiments of the disclosed technology.

FIG. 2 is a plan view illustrating a pixel group of an image sensing device based on some embodiments of the disclosed technology.

FIG. 3A is a cross-sectional view taken along a line I-I′ in FIG. 2. FIG. 3B is a cross-sectional view taken along a line II-II′ in FIG. 2.

FIGS. 4A to 4D are cross-sectional views illustrating a method of manufacturing an image sensing device based on some embodiments of the disclosed technology.

FIGS. 5A to 5D are cross-sectional views taken along a line II-II′ in FIG. 2 illustrating a method of manufacturing an image sensing device based on some embodiments of the disclosed technology.

### DETAILED DESCRIPTION

The disclosed technology can be implemented in various embodiments to provide image sensing devices that can secure more space for photoelectric converters while securing space for floating diffusion regions to improve full well capacity (FWC) of the photoelectric converters. The disclosed technology can also be implemented in some embodiments to provide image sensing devices that can increase a channel width of a pixel transistor to be able to have better operational characteristics. The disclosed technology can also be implemented in some embodiments to provide image sensing devices that can increase a contact area between a source/drain and a contact plug of a pixel transistor, thereby reducing a contact resistance.

In some example embodiments, the term “pixel group” may be used to indicate a pixel structure that includes a plurality of unit pixels (e.g., four unit pixels) that share a common component of the circuitry in the pixel group. The number of unit pixels in each pixel group may vary depending on implementations of the disclosed technology. In an embodiment, a pixel group may indicate a pixel structure that includes four unit pixels. In another embodiment, a pixel group may indicate a pixel structure that includes eight unit pixels. In another embodiment, a pixel group may indicate a pixel structure that includes two unit pixels.

In some implementations, a first direction D1 and a second direction D2 may be substantially perpendicular to each other. For example, the first direction D1 and the second direction D2 may correspond to an X-direction and a Y-direction, respectively, in an XY coordinate.

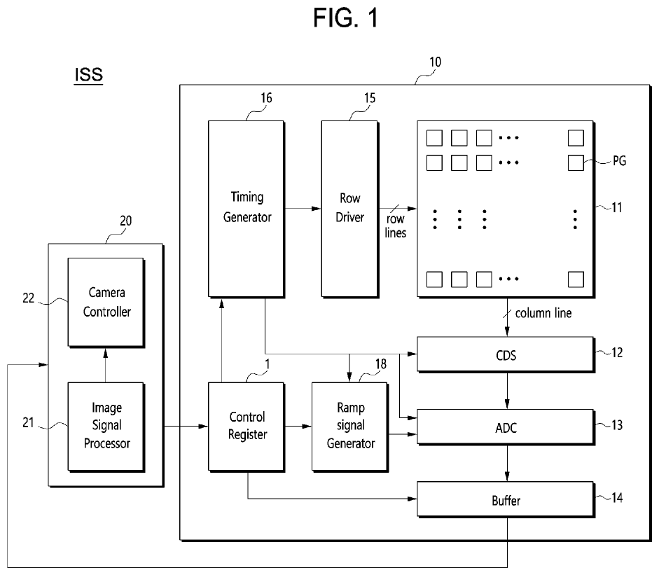

FIG. 1 is a block diagram illustrating an image sensing system based on some embodiments of the disclosed technology.

Referring to FIG. 1, an image sensing system ISS may include an image sensing device 10 and an image processor 20.

In some implementations, the image sensing device 10 may include a pixel array 11, a correlated double sampler (CDS) 12, an analog-digital converter (ADC) 13, a buffer 14, a row driver 15, a timing generator 16, a control register 17 and a ramp signal generator 18 with or without others. In other implementations, the image sensing device 10 may not include at least one of the above-mentioned elements.

The pixel array 11 may include a plurality of pixel groups PG arranged in a matrix. Each of the pixel groups PG may convert incident light from an object into electrical charge to be represented by electrical image signals. The pixel groups PG may transmit the electrical image signals to the CDS 12. The pixel array 11 may include a plurality of photo-sensitive elements to detect the incident light and convert the incident light into the electrical charge to be represented by the electrical image signals.

In some implementations, the image sensing system ISS may use the CDS 12 to remove an undesired offset value of pixels by sampling a pixel signal (e.g., electrical image signals) twice to remove the difference between these two samples. In one example, the CDS 12 may remove the undesired offset value of pixels by comparing pixel output voltages obtained before and after the light is incident on the pixels so that only pixel output voltages based on the incident light can be measured. In some embodiments of the disclosed technology, the CDS 12 may sample the electrical image signal received from the pixel groups PG of the pixel array 11. For example, the CDS 12 may sample a reference voltage level and a voltage level of the electrical image signal based on a timing signal provided from the timing generator 16, such as a clock signal. The CDS 12 may transmit an analog signal corresponding to a difference between the reference voltage level and the voltage level of the electrical image signal to the ADC 13.

The ADC 13 may convert the analog signal into a digital signal. The ADC 13 may then transmit the digital signal to the buffer 14.

The buffer 14 may latch or hold the digital signal. The buffer 14 may sequentially output the digital signal to the image processor 20. The buffer 14 may include a circuit configured to latch or hold the digital signal and a sense amplifier configured to amplify the digital signal.

The row driver 15 may activate selected pixels of the pixel array 11 in response to the signal of the timing generator 16. For example, the row driver 15 may generate selection signals for selecting one or more row lines and/or generate drive signals for activating the selected row line.

The timing generator 16 may generate the timing signal for controlling the CDS 12, the ADC13, the row driver 15 and the ramp signal generator 18.

The control register 17 may generate various control signals for controlling the buffer 14, the timing generator 16 and the ramp signal generator 18. The buffer 14, the timing generator 16 and the ramp signal generator 18 may be controlled individually or in common based on the control signals. The operations of the control register 17 may be controlled by a camera controller 22 in the image processor 20.

The ramp signal generator 18 may generate a ramp signal for controlling the image signal received from the buffer 14 based on control signals of the timing generator 16.

The image processor 20 may control the image sensing device 10 to process the image signal. Upon capturing, by a module lens, incident light from an object, the image processor 20 may process the image signal corresponding to the object and output an image corresponding to the image signal to an electronic device including a display device.

The image processor 20 may include an image signal processor 21, a camera controller 22 and a personal computer interface (PC I/F).

The camera controller 22 may control the control register 17 of the image sensing device 10 using an inter-integrated circuit I²C. The image signal processor 22 may process the image information received from the buffer 14. The image signal processor 22 may then send the image information to a display device.

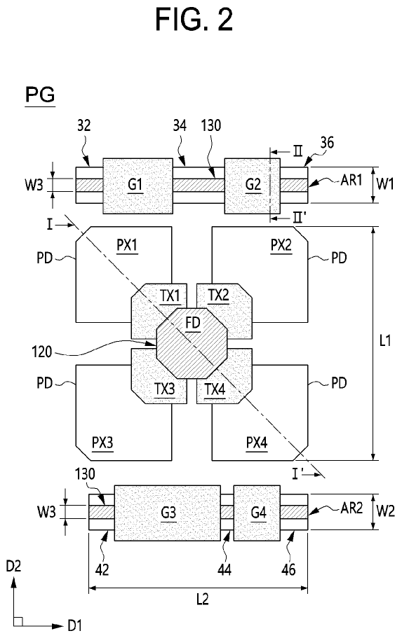

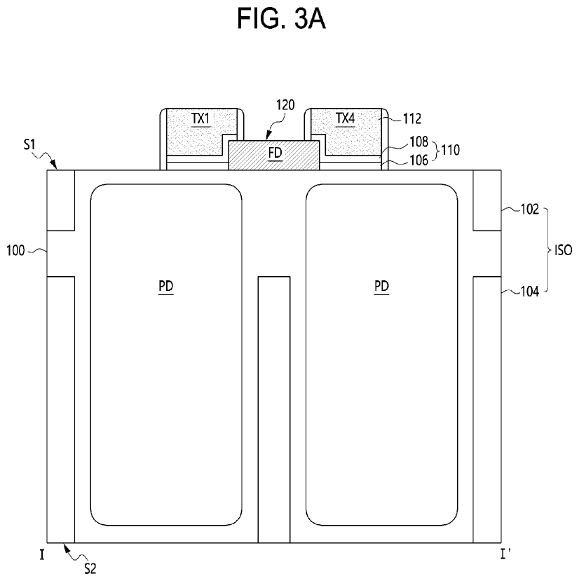

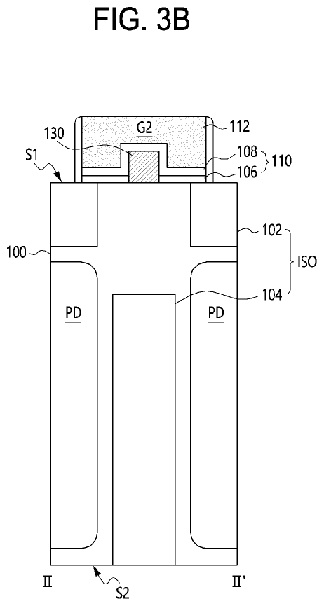

FIG. 2 is a plan view illustrating a pixel group of an image sensing device based on some embodiments of the disclosed technology. FIG. 3A is a cross-sectional view taken along a line I-I′ in FIG. 2, and FIG. 3B is a cross-sectional view taken along a line II-II′ in FIG. 2.

Referring to FIGS. 2, 3A and 3B, the pixel group PG in the pixel array 11 may include at least one unit pixel. For example, each of the pixel groups PG may include first to fourth unit pixels PX1-PX4. The first to fourth unit pixels PX1-PX4 may be arranged in a (2×2) matrix-shaped array. The first to fourth unit pixels PX1-PX4 may share a floating diffusion (floating diffusion region) FD. The first to fourth unit pixels PX1-PX4 may be radially arranged around the floating diffusion FD.

The first to fourth unit pixels PX1-PX4 may be electrically and/or optically isolated from one another. For example, the first to fourth unit pixels PX1-PX4 are physically separated from one another by an isolation structure ISO formed in a substrate 100. Regions of the substrate where the first to fourth unit pixels PX1-PX4 are formed can be defined by the isolation structure ISO. In some implementations, such regions may be referred to as “pixel region” or “light-receiving region.”

For example, the isolation structure ISO in contact with any one of a first surface S1 and a second surface S2 of the substrate 100 can define the regions where pixels may be formed. Alternately, the isolation structure ISO in contact with the first and second surfaces S1 and S2 of the substrate 100 can fully isolate pixels from each other. The first to fourth unit pixels PX1-PX4 in FIGS. 3A and 3B may be the pixels isolated from one another.

The isolation structure ISO may have any one of a trench type isolation structure and a junction type isolation structure. Alternatively, the isolation structure ISO may include a combination of the trench type and the junction type.

For example, the trench type isolation structure may include a trench formed in the substrate 100 and a gap-filling insulation layer in the trench. The trench type isolation structure may further include a fixed charging layer between an inner surface of trench and the gap-filling insulation layer.

In some implementations, the junction type isolation structure may include an impurity region in the substrate 100.

In example embodiments, the isolation structure ISO may include a first isolation structure 102 and a second isolation structure 104. The first isolation structure 102 may be exposed through the first surface S1 of the substrate 100, for example, a front surface of the substrate 100. The second isolation structure 104 may be exposed through the second surface S2 of the substrate 100, for example, a backside surface or a light incident surface of the substrate 100. For example, the first isolation structure 102 may be a shallow trench isolation (STI). The second isolation structure 104 may be a deep trench isolation (DTI). In some implementations, the first and second isolation structures 102 and 104 may be discontinuously formed to define the isolated pixels.

In some implementations, an impurity region 100a may be positioned between the first isolation structure 102 and the second isolation structure 104 aligned in a vertical direction, for example, a depth direction of the substrate 100. In some implementations, a part of the impurity region 100a may be formed at a space between the substrate 100 and the first isolation structure 102 and/or at a space between the substrate 100 and the second isolation structure 104.

Each of the first to fourth unit pixels PX1-PX4 may include a photoelectric converter PD formed in the substrate 100. The photoelectric converter PD may generate photo-charge in response to incident light. The photoelectric converter PD may include a photo diode, a photo transistor, a photo gate, a pinned photo diode, a combination of two or more of the photo diode, the photo transistor, the photo gate, and the pinned photo diode.

The substrate 100 may include a semiconductor substrate. The semiconductor substrate may have a single crystalline state. The semiconductor substrate 100 may include silicon. For example, the substrate 100 may have a thickness thinner than a thickness of a wafer on which the image sensing device is formed by a thinning process of the wafer. The substrate 100 may include an epitaxial layer formed by an epitaxial growth process. In some implementations, the substrate 100 may include a single crystalline silicon substrate on which the thinning process may be performed. The substrate 100 may include a material for generating photo-charge based on a wavelength band of the incident light.

Each of the first to fourth unit pixels PX1-PX4 may include a transfer transistor. The transfer transistor may transfer the photo-charge generated by the photoelectric converter PD in response to the incident light, to the floating diffusion FD. Each of the transfer transistors may include transfer gates TX1, T2, T3 or TX4. The transfer transistors may transfer the photo-charge in response to transfer signals applied to the transfer gates TX1-TX4. The photoelectric converter PD of each of the unit pixels PX1-PX4 may be used as a source of the transfer transistor. In some implementations, the common floating diffusion FD may be used as a drain electrode of the first to fourth transfer transistors in the pixel group PG.

The transfer gates TX1-TX4 of the transfer transistor may be formed on the first surface S1 of the substrate 100. The transfer gates TX1-TX4 may have a planar gate structure. For example, the transfer gates TX1-TX4 may have a recess gate structure configured to improve transfer efficiency of the photo-charges between the photoelectric converter PD and the floating diffusion FD. When the transfer gates TX1-TX4 have the recess gate structure, a bottom surface of the transfer gates TX1-TX4 may extend to a position adjacent to a surface of the photoelectric converter PD. Further, the bottom surface of the transfer gates TX1-TX4 having the recess gate structure may extend into the photoelectric converter PD.

The floating diffusion FD may include a first semiconductor pattern 120 to improve an FWC of the photoelectric converter PD. The first semiconductor pattern 120 may be formed on the first surface S1 of the substrate 100. The first semiconductor pattern 120 may be used as the floating diffusion FD by including conductive impurities.

For example, the floating diffusion FD may include a semiconductor pattern containing N type impurities. Because the floating diffusion FD may include the first semiconductor pattern 120 protruding from the first surface S1 of the substrate 100, the transfer transistor may have a sufficiently long channel length without reducing the light-receiving area of the photoelectric converter PD, i.e., the FWC. Because the floating diffusion FD may be positioned over the substrate 100, a space of the substrate 100 for a conventional floating diffusion FD may be used to form the photoelectric converter PD.

The first semiconductor pattern 120 that is used as the floating diffusion FD may have crystalline state substantially the same as the crystalline state of the substrate 100, i.e., the single crystalline state. The first semiconductor pattern 120 may include a material substantially the same as a material of the substrate 100. Alternatively, the material of the first semiconductor pattern 120 may be in the same group of the periodic table as the substrate 100. In example embodiments, the first semiconductor pattern 120 may include an epitaxial layer. In some implementations, the substrate 100 may include the silicon substrate, and the first semiconductor pattern 120 may include at least one of silicon and germanium.

Each of the transfer gates TX1-TX4 may partially overlap with the first semiconductor pattern 120 by driving the first semiconductor pattern 120 as the floating diffusion FD. Because the transfer gates TX1-TX4 may partially overlap with an end of the first semiconductor pattern 120 used as the floating diffusion FD, the photo-charge generated by the photoelectric converter PD may be transferred to the floating diffusion FD more efficiently. The transfer gates TX1-TX4 may include a gate insulation layer 110 and a gate conductive layer 112. The gate insulation layer 110 may be formed on the first surface S1 of the substrate 100 and the first semiconductor pattern 120. A thickness of the gate insulation layer 110 on the first surface S1 of the substrate 100 may be substantially the same as or different from a thickness of the gate insulation layer 110 on the first semiconductor pattern 120. In example embodiments, the gate insulation layer 110 may include a first insulation layer 106 and a second insulation layer 108. The first insulation layer 106 may be formed on the first surface S1 of the substrate 100. The second insulation layer 108 may be formed on the first insulation layer 106 and the first semiconductor pattern 120. For example, the gate insulating layer 110 including the stacked first and second insulation layers 106 and 108 may be interposed between the first surface S1 of the substrate 100 and the transfer gate TX1-TX4. The gate insulation layer 110 including only the second insulation layer 108 may be interposed between the first semiconductor pattern 120 and the transfer gate TX1-TX4.

In example embodiments, the first and second insulation layers 106 and 108 in the gate insulation layer 110 may include an oxide layer, a nitride layer, an oxynitride layer, a stack of the layers including two or more of the above-mentioned layers. In order to improve electrical characteristics at an interface between the first insulation layer 106 and the second insulation layer 108, the first and second insulation layers 106 and 108 may include substantially the same material.

A first active region AR1 and a second active region AR2 may be defined at a position outside the pixel group PG. The first active region AR1 and the second active region AR2 may be a region where the pixel transistors may be integrated. The pixel group PG may be positioned between the first active region AR1 and the second active region AR2 so that the first active region AR1 may face the second active region AR2. For example, the first active region AR1 and the second active region AR2 may extend in the first direction D1. A gap between the first active region AR1 and the second active region AR2 may be greater than a length (or width) L1 of the pixel group PG in the second direction D2. Alternatively, the first active region AR1 and the second active region AR2 may extend in parallel in the second direction D2. The gap between the first active region AR1 and the second active region AR2 may be equal to or greater than a length (or width) L2 of the pixel group PG in the first direction D1. The first active region AR1 and the second active region AR2 may intersect with each other.

The first active region AR1 and the second active region AR2 may be defined by the first isolation structure 102 of the isolation structure ISO. For example, the first active region AR1 and the second active region AR2 may be positioned on the first surface S1 of the substrate 100. The first active region AR1 and the second active region AR2 may have a bar shape including a long axis extending in the first direction D1 and a short axis extending in the second direction D1 in a planar view. Although not depicted in drawings, the first active region AR1 and the second active region AR2 may include a well tap configured to receive a substrate bias. The well tap may be positioned at an edge portion of the first active region AR1 and the second active region AR2.

Each of the first active region AR1 and the second active region AR2 may include a second semiconductor pattern 130 protruding from the first surface S1 of the substrate 100. The second semiconductor pattern 130 may have a bar shape extending in the first direction D1 in the planar view. In example embodiments, a length (or width) W3 of the second semiconductor pattern 130 in the second direction D2 may be shorter than a length (or width) W1 of the first active region AR1 in the second direction D2 and a length (or width) W2 of the second active region AR2 in the second direction D2. Further, each of the second semiconductor patterns 130 of the first active region AR1 and the second active region AR2 may be positioned at a center portion of the first active region AR1 and the second active region AR2. An extending length L2 of the second semiconductor pattern 130 in the first direction D1 may be substantially the same as a length (or width) of the first active region AR1 in the first direction D1 and a length (or width) of the second active region AR2 in the first direction D1. The second semiconductor pattern 130 may include a material substantially the same as a material of the first semiconductor pattern 120. That is, the second semiconductor pattern 130 may be formed simultaneously with the first semiconductor pattern 120 by the same process. Thus, the first semiconductor pattern 120 and the second semiconductor pattern 130 may have the same height from the first surface S1 of the substrate 100.

A conversion gain transistor having a conversion gain gate G1 and a reset transistor having a reset gate G2 may be integrated in the first active region AR1 with the second semiconductor pattern 130. The conversion gain transistor and the reset transistor may partially share a junction region to secure a maximum channel area in a restricted area, for example, an area of the first active region AR1.

The conversion gain transistor may convert a capacitance of the floating diffusion FD in response to a conversion gain signal applied to the conversion gain gate G1. The reset transistor may initialize an electric potential or voltage of the floating diffusion FD to a specific level, for example, a power voltage level in response to a reset signal applied to the reset gate G2.

The first active region AR1 may include a plurality of junction regions 32, 34 and 36. Each of the junction regions 32, 34 and 36 may be used as a source/drain electrode of the conversion gain transistor and the reset transistor. For example, the first junction region 32 may be used as the source electrode of the conversion gain transistor. The third junction region 36 may be used as the drain electrode of the reset transistor. The second junction region 34 may be used as the drain electrode of the conversion gain transistor and the source of the reset transistor. The source of the conversion gain transistor, for example, the first junction region 32 may be electrically connected with the source of the conversion gain transistor in another pixel group PG or a ground voltage terminal. The drain electrode of the reset transistor, for example, the third junction region 36 may be electrically connected with the power voltage terminal. The second junction region 34 as the drain of the conversion gain transistor and the source of the reset transistor may be electrically connected with the floating diffusion FD through a conductive line.

A drive transistor having a drive gate G3 and a selection transistor having a selection gate G4 may be integrated in the second active region AR2 with the second semiconductor pattern 130. The drive transistor and the selection transistor may partially share a junction region to secure a maximum channel area in a restricted area, for example, an area of the second active region AR2.

The drive gate G3 of the drive transistor may be electrically connected with the floating diffusion FD. The drive transistor may generate an amplified output signal in response to an amount of the photo-charges stored in the floating diffusion FD. In some implementations, the drive transistor may be referred to as a source follower transistor. The selection gate G4 of the selection transistor may receive a selection signal applied through a row line. The selection gate G4 may transmit the output signal from the drive transistor in response to the selection signal to a column line.

The second active region AR2 may include a plurality of junction regions 42, 44 and 46. Each of the junction regions 42, 44 and 46 may be used as a source/drain electrode of the drive transistor and the selection transistor. For example, the fourth junction region 42 may be used as the drain electrode of the drive transistor. The sixth junction region 46 may be used as the source electrode of the selection transistor. The fifth junction region 44 may be used as the source electrode of the drive transistor and the drain electrode of the selection transistor. The drain electrode of the drive transistor, for example, the fourth junction region 42 may be electrically connected with the power voltage terminal. The drive gate G3 may be electrically connected to the floating diffusion FD. Although not depicted in drawings, the drive gate G3, the drain 34 of the conversion gain transistor and the source 34 of the reset transistor may be electrically connected with the floating diffusion FD. The source of the selection transistor may be electrically connected to the column line.

Each of the gates of the pixel transistors, i.e., the conversion gain gate G1, the reset gate G2, the drive gate G3 and the selection gate G4 may include the gate insulation layer 110 and the gate conductive layer 112 stacked on the gate insulation layer 110.

The gate insulation layer 110 of the conversion gain gate G1, the gate insulation layer 110 of the reset gate G2, the gate insulation layer 110 of the drive gate G3 and the gate insulation layer 110 of the selection gate G4 may have different thicknesses. For example, a thickness of the gate insulation layer 110 in contact with the first surface S1 of the substrate 100 may be substantially equal to or different from a thickness of the gate insulation layer 110 in contact with the second semiconductor pattern 130.

For example, the gate insulation layers 110 of the conversion gain gate G1, the reset gate G2, the drive gate G3 and the selection gate G4 may include the first insulation layer 106 and the second insulation layer 108, respectively. The first insulation layer 106 may be formed on the first surface S1 of the substrate 100. The second insulation layer 108 may be formed on the first insulation layer 106 and the second semiconductor pattern 130. That is, the gate insulation layer 110 including the stacked first and second insulation layers 106 and 108 may be positioned between the first surface S1 of the substrate 100, and the conversion gain gate G1, the reset gate G2, the drive gate G3 and the selection gate G4, respectively. Only the second insulation layer 108 may be positioned between the second semiconductor pattern 130, and the conversion gain gate G1, the reset gate G2, the drive gate G3 and the selection gate G4, respectively.

Each of the conversion gain gate G1, the reset gate G2, the drive gate G3 and the selection gate G4 may be configured to cover the second semiconductor pattern 130. Thus, each of the conversion gain gate G1, the reset gate G2, the drive gate G3 and the selection gate G4 may have a fin gate structure that overlaps with a sidewall and an upper surface of the second semiconductor pattern 130 in a channel width direction, for example, the first direction D1. Therefore, the channel width of the pixel transistor may be increased to improve a current driving force of the pixel transistor and to suppress noise. In some implementations, because the drive transistor occupying a relatively large channel width may perform a source follower operation, operation characteristics may be improved and an output image quality may also be improved.

The second semiconductor pattern 130 may correspond to a part of the first to sixth junction regions 32, 34, 36, 42, 44 and 46. Thus, an area of the junction region of the pixel transistors may be enlarged by a surface area of the second semiconductor pattern 130. Therefore, a contact area between the junction regions of the pixel transistors and contact plugs connected to the junction regions may be secured to improve a contact resistance, thereby improving the signal transmission efficiency. Further, a shallow junction may be formed due to the second semiconductor pattern 130 to improve electrical characteristics of the pixel transistors.

In some example embodiments, the image sensing device may form the floating diffusion FD using the first semiconductor pattern 120 protruding from the substrate 100 to improve the FWC of the photoelectric converter FD. Further, the transfer gate TX1-TX4 may partially overlap with the side surface of the first semiconductor pattern 120 to improve the transmission efficiency of the photo-charges between the photoelectric converter PD and the floating diffusion FD.

Furthermore, the image sensing device may form the second semiconductor pattern 130 protruding from the first active region AR1 and the second active region AR2 of the substrate 100. Thus, the channel area of the pixel transistor, particularly, the channel width of the pixel transistor integrated in the first active region AR1 and the second active region AR2 may be increased to improve the operation characteristics of the pixel transistor. Moreover, a contact area between the source/drain of the pixel transistor and the contact plug may be increased to improve the signal transmission characteristics. Because the second semiconductor pattern 130 may be protruding from the substrate 100, the FWC of the photoelectric converter PD may also be improved similarly to the function of the first semiconductor pattern 120. As a result, the image sensing device may have improved operation reliability.

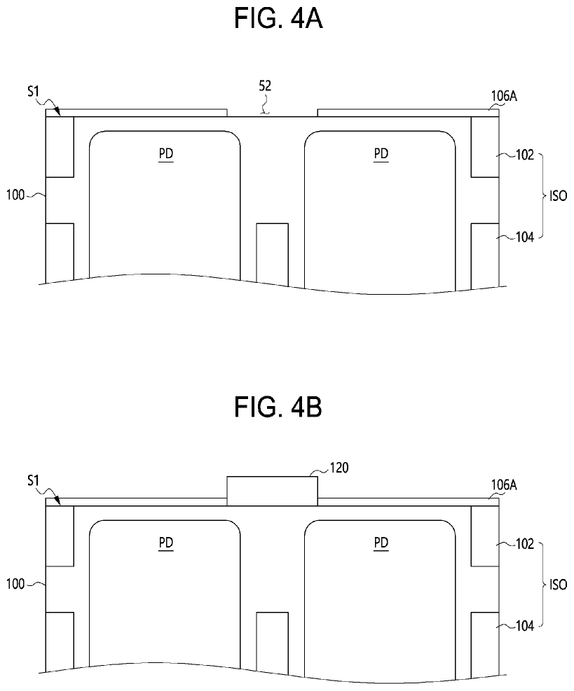

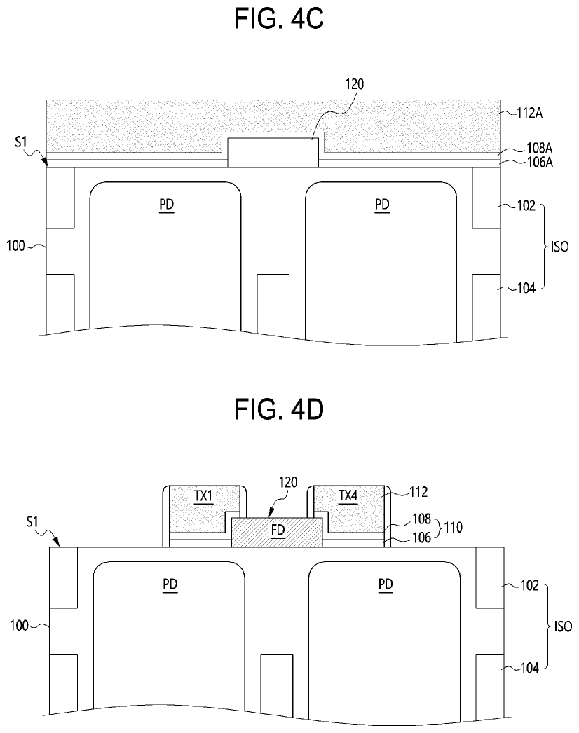

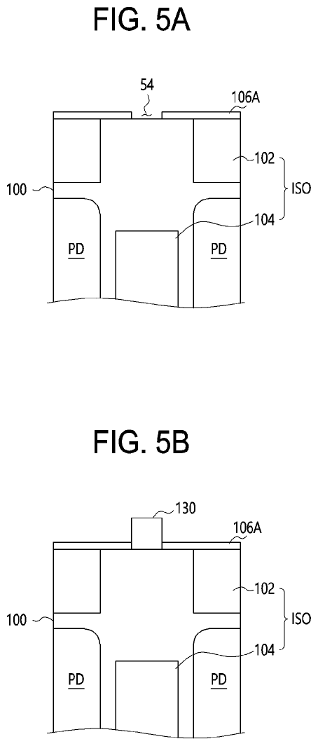

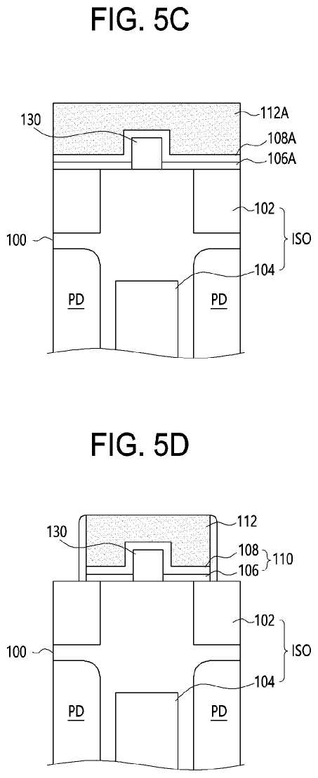

FIGS. 4A to 4D are cross-sectional views illustrating a method of manufacturing an image sensing device based on some embodiments of the disclosed technology and FIGS. 5A to 5D are cross-sectional views taken along a line II-II′ in FIG. 2 illustrating a method of manufacturing an image sensing device based on some embodiments of the disclosed technology.

Referring to FIGS. 4A and 5A, the isolation structure ISO may be formed in the substrate 100 to isolate the photoelectric converters PD from each other. The substrate 100 may include the light-receiving region or the pixel region and the active regions defined by the isolation structure ISO. The photoelectric converter PD may be formed in the light-receiving region. The pixel transistors may be formed in the active regions.

The photoelectric converter PA may include a photodiode, a photo transistor, a photo gate, a pinned photo diode, or a combination of two or more of the photodiode, the photo transistor, the photo gate, and the pinned photo diode. In example embodiments, the photoelectric converter PD may include the photo diode.

Particularly, the photoelectric converter PD including the photo diode may be formed in the substrate 100. The photoelectric converter PD may include at least one first impurity region and at least one second impurity region. The first and second impurity regions may have complementary conductivity types. The first and second impurity regions may overlap with each other in a depth direction of the substrate 100 or in a direction substantially parallel to the first surface S1 or the second surface S2 of the substrate 100. For example, the first impurity region may include P type impurities. The second impurity region may include N type impurities.

In example embodiments, a plurality of the second impurity region may be formed in the substrate 100 to have a depth. A plurality of the first impurity region may be configured to surround the second impurity region. Any one of the first impurity regions may be in contact with the first surface S1 of the substrate 100. Any one of the first impurity regions may be in contact with the second surface S2 of the substrate 100. Any one of the first impurity regions may be in contact with the adjacent isolation structure ISO. The first impurity region in contact with the first and second surfaces S1 and S2 of the substrate 100 and the isolation structure ISO may reduce noises caused by a defect.

The isolation structure ISO may include the trench type isolation structure, a junction type isolation structure, a combination thereof, etc. The trench type isolation structure may be configured to physically isolate the photoelectric converters PD from each other. The junction type isolation structure may form a potential barrier to electrically isolate the photoelectric converters PD from each other. In example embodiments, the isolation structure ISO may be the trench type isolation structure. Thus, the isolation structure ISO may include a first isolation structure 102 in the first surface S1 of the substrate 100 and a second isolation structure 104 formed in the second surface S2 of the substrate 100. The first isolation structure 102 may have the STI to isolate the pixel transistors from each other. The second isolation structure 104 may have the DTI to isolate the photoelectric converters PD from each other. In some implementations, the second isolation structure 104 may prevent an optical crosstalk.

A first insulation layer 106A may be formed on the first surface S1 of the substrate 100. The first insulation layer 106A may be etched to form a first opening 52 and a second opening 54. The first insulation layer 106A may include an oxide layer, a nitride layer, an oxynitride layer, a combination thereof, etc.

The first opening 52 may correspond to a region where the floating diffusion is to be formed. The second opening 54 may correspond to a part of the active region of the pixel transistors. The first opening 52 and the second opening 54 may be formed by a photolithography process and/or an etching process.

Referring to FIGS. 4B and 5B, the first surface S1 of the substrate 100 exposed through the first opening 52 and the second opening 54 may epitaxially grow to simultaneously form the first semiconductor pattern 120 in the first opening 52 and the second semiconductor pattern 130 in the second opening 54.

The first and second semiconductor patterns 120 and 130 may include a material substantially the same as the material of the substrate 100. Alternatively, the material of the first and second semiconductor patterns 120 and 130 may be in the same group of the periodic table the material of the substrate 100. When the substrate 100 may include silicon, the first and second semiconductor patterns 120 and 130 may include a silicon layer or a germanium included in the same group of the periodic table. In some implementations, the first and second semiconductor patterns 120 and 130 may include a layer containing silicon and germanium. Because the first and second semiconductor patterns 120 and 130 may be simultaneously formed, the first and second semiconductor patterns 120 and 130 may have the same height from the substrate 100.

Referring to FIGS. 4C and 5C, a second insulation layer 108A may be formed on the first surface S1 of the substrate 100 to cover the first and second semiconductor patterns 120 and 130. The second insulation layer 108A may have a uniform thickness. The second insulation layer 108A may include an oxide layer, a nitride layer, an oxynitride layer, or a combination of two or more of the oxide layer, the nitride layer, and the oxynitride layer. In order to improve interface characteristics between the first insulation layer 106A and the second insulation layer 108A, the material of the second insulation layer 108A may be substantially the same as the material of the first insulation layer 106A.

A gate conductive layer 112A may be formed on the second insulation layer 108A. The gate conductive layer 112A may include various conductive materials.

Referring to FIGS. 4D and 5D, a mask pattern may be formed on the gate conductive layer 112A. The gate conductive layer 112A, the second insulation layer 108A and the first insulation layer 106A may be etched using the mask pattern as an etch barrier to form gates TX1, TX2 and G2. FIGS. 4D and 5D show the first transfer gate TX1, the fourth transfer gate TX4 and the reset gate G2. The second transfer gate TX2, the third transfer gate TX3, the conversion gain gate G1, the drive gate G3 and the selection gate G4 in FIG. 2 may also be defined.

Impurities may be implanted into the first semiconductor pattern 120 to form the floating diffusion FD in the first semiconductor pattern 120. Impurities may be implanted into the substrate 100 in the active region to form the junction regions 32, 34, 36, 42, 44, 46.

In some example embodiments, the image sensing device may include the semiconductor patterns formed over the substrate corresponding to the floating diffusion and the channel region of the pixel transistor to improve the FWC of the photoelectric converter and the operation characteristics of the pixel transistor.

Only limited examples of implementations or embodiments of the disclosed technology are described or illustrated. Variations and enhancements for the disclosed implementations or embodiments and other implementations or embodiments are possible based on what is disclosed and illustrated in this patent document.

What is claimed is:

1. An image sensing device comprising:
a substrate;
a light-receiving region supported by the substrate to receive incident light and structured to include a photoelectric converter configured to detect the incident light to generate photo-charge carrying an image in the incident light;
at least one active region supported by the substrate and located adjacent to the light-receiving region;
a first gate formed over an upper surface of the substrate such that a first end of the first gate is disposed over the photoelectric converter;
a first semiconductor pattern formed over the upper surface of the substrate at a second end of the first gate opposite to the first end and including a floating diffusion region, the first semiconductor pattern having a first height from the upper surface of the substrate;
a second semiconductor pattern formed over the upper surface of the substrate corresponding to the active region, the second semiconductor pattern having a second height from the upper surface of the substrate; and
a second gate formed over the upper surface of the substrate corresponding to the active region to cover the second semiconductor pattern.

2. The image sensing device of claim 1, wherein the first gate includes a first portion and a second portion, the first portion disposed over the photoelectric converter, the second portion disposed on a sidewall of the first semiconductor pattern.

3. The image sensing device of claim 1, wherein the first gate comprises a gate insulation layer and a gate conductive layer disposed on the gate insulation layer, wherein a thickness of a portion of the gate insulation layer located between the first gate and the photoelectric converter is thicker than a thickness of another portion of the gate insulation layer located between the first gate and the floating diffusion region.

4. The image sensing device of claim 1, wherein the active region and the second semiconductor pattern have a same width in a first direction, a width of the second semiconductor pattern in a second direction is shorter than a width of the active region in the second direction, wherein the second direction is substantially perpendicular to the first direction.

5. The image sensing device of claim 4, wherein the second semiconductor pattern is positioned in a region that includes a center of the active region.

6. The image sensing device of claim 1, wherein the second gate is in contact with: an upper surface of the second semiconductor pattern; both sidewalls extending from both ends of the upper surface of the second semiconductor pattern; and the active regions at both sides of the second semiconductor pattern.

7. The image sensing device of claim 1, further comprising a junction region formed in the active region and the second semiconductor pattern at both sides of the second gate.

8. The image sensing device of claim 1, wherein the second gate includes a gate electrode of any one of; a reset transistor configured to initialize the floating diffusion region to a power voltage level; a drive transistor configured to generate an output signal corresponding to an amount of photo-charge stored in the floating diffusion region; a selection transistor configured to transmit the output signal to a column line; or a conversion gain transistor configured to change a capacitance of the floating diffusion region.

9. The image sensing device of claim 1, wherein the second gate includes a gate insulation layer and a gate conductive layer stacked on the gate insulation layer, wherein a thickness of a portion of the gate insulation layer located between the second gate and the substrate in the active region is thicker than a thickness of another portion of the gate insulation layer located between the second gate and the second semiconductor pattern.

10. The image sensing device of claim 1, wherein the first and second semiconductor patterns comprise an epitaxial layer including a material that is substantially identical to a material included in the substrate, wherein the first height is substantially identical to the second height.

11. An image sensing device comprising:
a substrate;
first and second semiconductor patterns supported by the substrate and protruding from the substrate, the first semiconductor pattern including a floating diffusion region;
at least one photoelectric converter configured to detect incident light to generate photo-charge carrying an image in the incident light, the at least one photoelectric converter formed in a portion of the substrate adjacent to the floating diffusion region to generate photo-charge corresponding to incident light;
at least one transfer transistor supported by the substrate and configured to transfer the photo-charge generated by the at least one photoelectric converter to the floating diffusion region in response to a transfer signal;
a reset transistor supported by the substrate and configured to initialize the floating diffusion region to a power voltage level in response to a reset signal;
a drive transistor supported by the substrate and configured to generate an output signal corresponding to an amount of the photo-charge stored in the floating diffusion; and
a selection transistor supported by the substrate and configured to output the output signal generated by the drive transistor, in response to a selection signal,
wherein at least one of the reset transistor, the drive transistor or the selection transistor comprises a fin gate structured to surround a side surface and an upper surface of the second semiconductor pattern.

12. The image sensing device of claim 11, further comprising a conversion gain transistor supported by the substrate and configured to change a capacitance of the floating diffusion region in response to a conversion gain signal,
wherein the conversion gain transistor comprises a fin gate structured to surround the side surface and the upper surface of the second semiconductor pattern.

13. The image sensing device of claim 12, wherein the fin gate comprises a gate insulation layer and a gate conductive layer disposed on the gate insulation layer, wherein a thickness of a portion of the gate insulation layer located between the gate and the substrate is different from a thickness of a portion of the gate insulation layer located between the gate and the second semiconductor pattern.

14. The image sensing device of claim 11, wherein a portion of a gate electrode of the transfer transistor is in contact with a sidewall of the first semiconductor pattern.

15. The image sensing device of claim 14, wherein the gate of the transfer transistor comprises a gate insulation layer and a gate conductive layer disposed on the gate insulation layer, wherein a thickness of a portion of the gate insulation layer located between the gate and the substrate is different from a thickness of a portion of the gate insulation layer located between the gate and the first semiconductor pattern.

16. A method of manufacturing an image sensing device, the method comprising:
forming a first insulation layer on a substrate that includes a light-receiving region and an active region adjacent to the light-receiving region, wherein the light-receiving region includes a photoelectric converter configured to detect incident light to generate photo-charge carrying an image in the incident light;
selectively etching the first insulation layer to form a first opening to partially expose the light-receiving region of the substrate and a second opening to partially expose the active region of the substrate;
forming first and second semiconductor patterns on the substrate exposed through the first and second openings;
forming a second insulation layer on the first insulation layer, the first semiconductor pattern and the second semiconductor pattern;
forming a gate conductive layer on the second insulation layer;
etching the gate conductive layer, the second insulation layer and the first insulation layer to form a first gate over the light-receiving region of the substrate and a second gate over the active region of the substrate; and
implanting impurities into the first semiconductor pattern to form a floating diffusion.

17. The method of claim 16, wherein the first and second semiconductor patterns are formed by a selective epitaxial growth process.

18. The method of claim 17, wherein the first and second semiconductor patterns are formed by epitaxially growing the substrate by a same thickness.

19. The method of claim 16, wherein the gate conductive layer over the light-receiving region of the substrate is etched to form the first gate positioned over one end of the light-receiving region to cover a sidewall of the first semiconductor pattern, and the gate conductive layer over the active region is etched to form the second gate to cover the second semiconductor pattern.

20. The method of claim 16, further comprising implanting impurities into the active region and the second semiconductor pattern at both sides of the second gate to form junction regions.
